(19) United States
(12) Patent Application Publication
(10) Pub. No.: US 2002/0072222 A1
(43) Pub. Date: Jun. 13, 2002

(54) Method for preventing Cu cross contamination

(75) Inventor: Ching-Yu Chang, Ilan Hsien (TW)

Correspondence Address: LOWE HAUPTMAN GOPSTEIN GILMAN & BERNER, LLP, Suite 310, 1700 Diagonal Road, Alexandria, VA, 22314, US

(73) Assignee: MACRONIX INTERNATIONAL CO., LTD

(21) Appl. No.: 09/731,753

(22) Filed: Dec. 8, 2000

(51) Int. Cl. H01L 21/4763

(52) U.S. Cl. 438/627; 438/648

(57) ABSTRACT

In accordance with the present invention, a new method is provided for fabricating a protect layer on the wafer's backside before preceding a Cu process. An inter-layer dielectric is deposited above the main device areas before forming ohmic contacts, and the wafer is smoothened by chemical mechanical polishing and then reversed when the polishing process finished. A metal barrier layer is deposited above the wafer's backside to provide protection against the Cu cross contamination during Cu process. An oxide layer is deposited above the barrier layer to cover the barrier layer, which may certainly make sure the barrier layer not contact with the holder directly.

### FIELD OF THE INVENTION

The present invention relates to a semiconductor manufacture process, and more specifically to a method for forming a barrier layer

### BACKGROUND OF THE INVENTION

It is necessary to fabricate many active devices on a single semiconductor substrate so as to build an integrated circuit operating with desired action. Various kinds of devices with different functions, such as transistors, resistors and capacitors, are formed together. It is impossible to build hundreds of thousands of semiconductor devices on a single chip. The devices on the substrate must be electrically isolated each other so as to ensure the individual function. The specific devices must be coupled together with conducting wire to implement the desired circuit function. However, it is very difficult to minimize the size of transistors due to the technology limitation of photolithography and etching. The impedance of the conducting wire is therefore the important factor of device speed. The scaling down of device may narrow the width of conducting wire, which causes the impedance of conducting wire increase and the problem of time delay.

Low resistivity material for fabricating conducting wire is therefore desired to correct the time delay coming from the high impedance. Cu is generally the preferred conductive wire material due to its low resistivity and high electromigration. However, the application of Cu may suffer from some problems. Since Cu may diffuse into dielectric material such as silicon oxide and oxygen-containing polymer it is therefore necessary to form a barrier layer between them to forbid the Cu diffusing to cause cross contamination. The material of barrier layer is selected from the group consisting of TiN, TiW, TaN , TaW or the foregoing combination and so on.

Referring to FIG. 1, it shows a conventional process before Cu process. This conventional process is to form an inter-layer dielectric 104 above the main device areas 102 before forming an ohmic contact and then proceeds to Cu process. However, the barrier layer to prevent the cross contamination due to the Cu diffusion is only formed on the wafer's front side, which may not prevent the Cu 106 to diffuse into the chip from the wafer's backside. The Cu cross contamination may affect the yields and FAB's productively. It exists an instant requirement to prevent the Cu cross contamination from the wafer's backside when preceding Cu process.

### SUMMARY OF THE INVENTION

It is therefore an objective of the present invention to provide a method for forming a protect layer to prevent the Cu cross contamination from the wafer's backside when preceding Cu process.

In accordance with the above objectives of the present invention, a new method is provided for fabricating a protect layer on the wafer's backside before preceding Cu process. An inter-layer dielectric is deposited above the main device areas before forming ohmic contacts, and then the chip is reversed to deposit a metal barrier layer above the wafer's backside. The metal barrier layer may provide protection against the Cu cross contamination during Cu process. An oxide layer is deposited above the barrier layer to cover the barrier layer, which may certainly make sure the barrier layer not contact with the holder directly.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is the cross section view of semiconductor wafer illustrating the Cu adheres on the wafer's backside;

FIG. 2 is the cross section view of semiconductor wafer according to the present invention illustrating the step of depositing an inter-layer dielectric above the main device areas;

FIG. 3 is the cross section view of semiconductor wafer according to the present invention illustrating the step of depositing a barrier layer above the wafer's backside;

FIG. 4 is the cross section view of semiconductor wafer according to the present invention illustrating the step of depositing an oxide layer above the barrier layer;

FIG. 5 is the cross section view of semiconductor wafer according to the present invention illustrating the step of depositing an Cu thin film layer above the inter-layer dielectric.

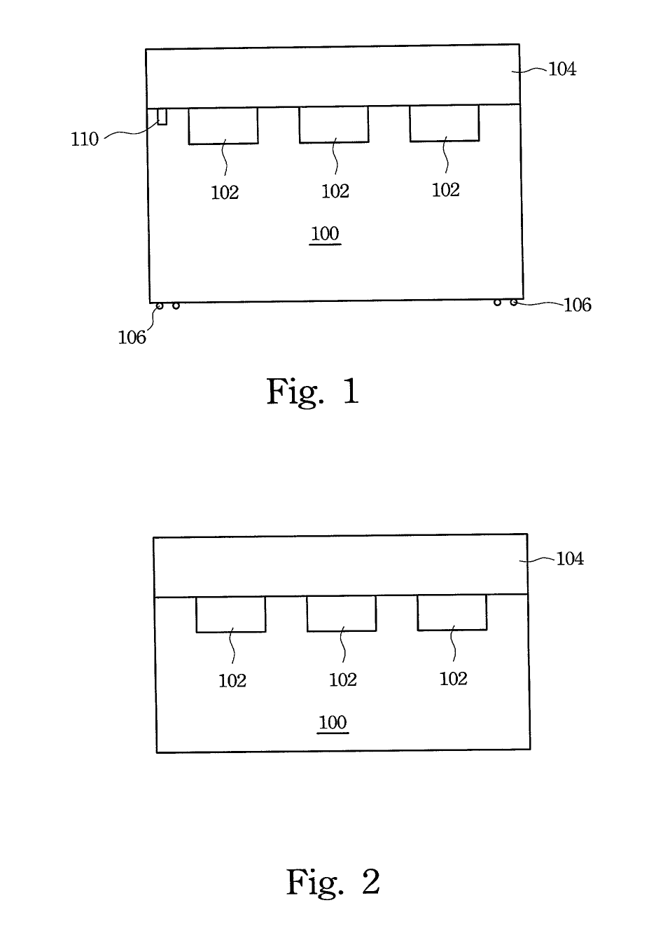

### DETAILED DESCRIPTION OF THE PREFERRED EMBODIMENT

Some barrier layers may deposit above the wafer's front side before proceeding Cu process, which may effectively provide protection against the Cu cross contamination. However, the barrier layer to prevent the cross contamination due to the Cu diffusion is only formed on the wafer's front side, which may not prevent the Cu to diffuse into the chip from the wafer's backside. The present invention provide a method of fabricating a barrier layer above the wafer's backside to resolve the Cu cross contamination.

Referring to FIG. 2, a plurality of main device areas 102 are formed on a silicon wafer 100. Cu conducting wire is used to perform the signal transmission between the main device areas 102 due to the low resistivity of Cu material. An inter-layer dielectric 104, such as borophosphosilicate glass (BPSG), is deposited above the main device areas 102 before proceeding the Cu process and the thickness of the inter-layer dielectric 104 is within the range about 3000 to 10000 Angstrom. The wafer then proceeds a chemical mechanical polishing to smoothen the inter-layer dielectric 104.

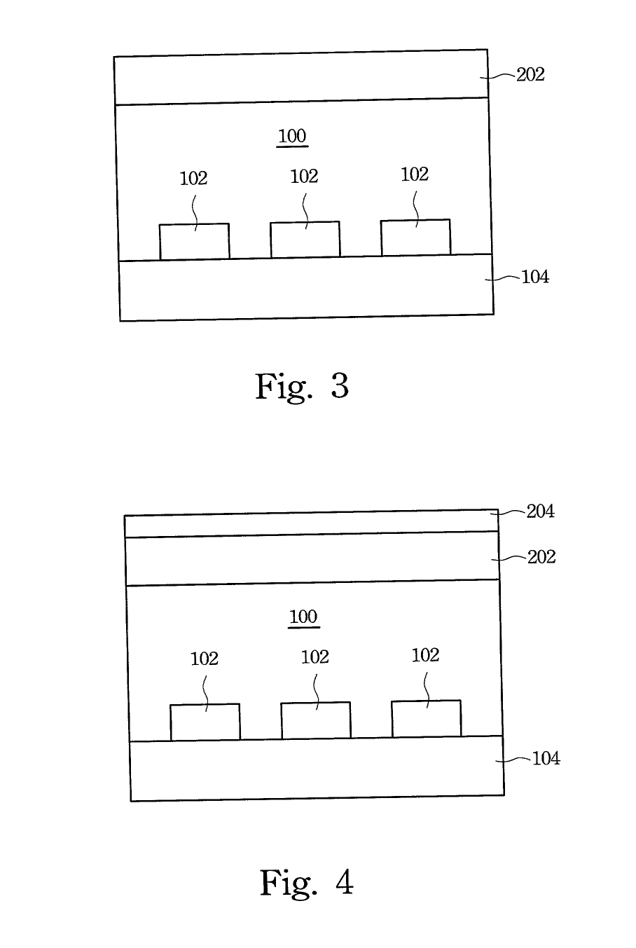

Referring to FIG. 3, the wafer is reversed and a metal layer is deposited above the wafer's backside as a barrier layer by the sputtering method, wherein the material used to form barrier layer is selected from the group consisting of Ti, TiN, TiW, TaN, TaW or the foregoing combination. The barrier layer is used to provide protection against the Cu cross contamination during Cu process. The metallic bond of barrier layer may effectively resist the Cu diffusing into the wafer. The thickness of the barrier layer is at least 10 Angstrom.

Referring to FIG. 4, a protection layer 204 is deposited above the barrier layer 202 to all cover the barrier layer 202 by the chemical vapor deposition (CVD) method, which may certainly make sure the barrier layer not contact with the holder (not shown in the figure) directly when proceeding the Cu process, wherein the material used to form a protection layer 204 is selected from the group consisting of oxide, Si₃N₄ or USG. The protection layer 204 is at least 20 angstroms.

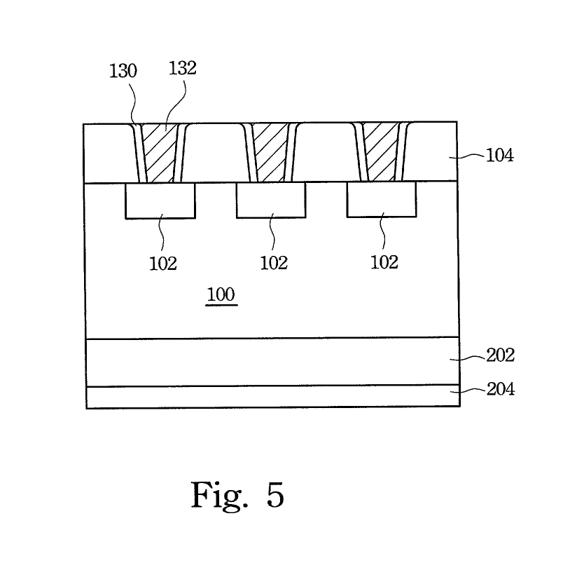

Referring to FIG. 5, the wafer is reversed again and the protection layer 204 may contact with the holder directly (not shown in the figure), and then proceeds the photolithography and etching process so as to form a conductive hole on the inter-layer dielectric 104 to proceed metallization process. The Ti 130 is deposited on the conductive hole as a glue layer by the sputtering method, and then a Cu thin film layer 132 is deposited above the glue layer. The wafer then proceeds a chemical mechanical polishing to smoothen the Cu thin film layer 132 and Ti 130. The protection layer 204 may prevent the Cu cross contamination happening on the wafer's backside from the Cu process. A semiconductor device having a protection layer to prevent Cu cross contamination is finished.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for preventing Cu cross contamination on a wafer comprising the steps of:
forming a inter layer dielectric above a silicon wafer having a plurality of main device areas; and
forming a metal barrier layer above the wafer's backside.

2. The method according to claim 1, wherein the material of said barrier layer is selected from the group consisting of Ti, TiN, TiW, TaN, TaW or the foregoing combination.

3. The method according to claim 1, wherein the thickness of the barrier layer is at least 10 angstroms.

4. A method for preventing Cu cross contamination on a wafer comprising the steps of:
forming a metal barrier layer above the wafer's backside; and
forming a protection layer above said metal barrier layer.

5. The method according to claim 4, wherein the material of said barrier layer is selected from the group consisting of Ti, TiN, TiW, TaN, TaW or the foregoing combination.

6. The method according to claim 4, wherein the material of said protection layer is selected from the group consisting of oxide, Si₃N₄ or USG.

7. The method according to claim 4, wherein the thickness of the barrier layer is at least 10 Angstroms.

8. The method according to claim 4, wherein the thickness of the protection layer is at least 20 Angstroms.

9. A method for preventing Cu cross contamination on a wafer comprising the steps of:
forming a inter layer dielectric above a silicon wafer having a plurality of main device areas;
reversing said silicon wafer to expose said wafer's backside;
forming a metal barrier layer above said silicon wafer's backside;
forming a protection layer above said metal barrier layer; and
reversing said silicon wafer to expose said silicon wafer's inter layer dielectric and then proceeding a Cu process.

10. The method according to claim 9, wherein the material of said barrier layer is selected from the group consisting of Ti, TiN, TiW, TaN, TaW or the foregoing combination.

11. The method according to claim 9, wherein the material of said protection layer is selected from the group consisting of oxide, Si₃N₄ or USG.

12. The method according to claim 9, wherein the thickness of the barrier layer is at least 10 Angstroms.

13. The method according to claim 9, wherein the thickness of the protection layer is at least 20 Angstroms.
